(19) United States
(12) Patent Application Publication
(10) Pub. No.: US 2019/0146253 A1
(43) Pub. Date: May 16, 2019

(54) DISPLAY PANEL AND DISPLAY DEVICE

(71) Applicants: BOE TECHNOLOGY GROUP CO., LTD., Beijing (CN); Chengdu BOE Optoelectronics Technology Co., Ltd., Chengdu (CN)

(72) Inventors: Wei Guo, Beijing (CN); Pengcheng Zang, Beijing (CN); Xiongcan Zuo, Beijing (CN); Jianjun Li, Beijing (CN)

(21) Appl. No.: 15/927,012

(22) Filed: Mar. 20, 2018

(30) Foreign Application Priority Data
Nov. 16, 2017 (CN) 201711139669.9

(51) Int. Cl. G02F 1/1368; H01L 27/12; G02F 1/1343

(52) U.S. Cl. CPC G02F 1/1368; G02F 2001/133354; G02F 1/134309; H01L 27/1214

(57) ABSTRACT

Disclosed are a display panel and a display device. The display panel includes an array substrate, an opposite substrate, a separator positioned between the array substrate and the opposite substrate to support these two substrates, and a conducting layer disposed between the separator and the array substrate and electrically connected with a gate electrode on the array substrate.

### CROSS REFERENCE TO RELATED APPLICATION

The present application claims a priority benefit of Chinese Patent Application No. 201711139669.9, filed on Nov. 16, 2017, the entire contents thereof being incorporated herein by reference.

### TECHNICAL FIELD

The present disclosure relates to the technical field of display, and particularly to a display panel and a display device.

### BACKGROUND

In the current LCD (Liquid Crystal Display) panels, a phenomenon of poor blue spot is liable to occur during use, affecting the display effect.

### SUMMARY

The present disclosure provides a display panel including an array substrate, an opposite substrate, and a separator positioned between the array substrate and the opposite substrate to support these two substrates, wherein the display panel further includes a conducting layer disposed between the separator and the array substrate and electrically connected with a gate electrode on the array substrate.

The display panel according to the present disclosure may further comprise the following additional technical features.

In an embodiment of the present disclosure, the conducting layer separates the separator and the array substrate, and a projection of an end surface of the separator facing the array substrate towards the conducting layer is covered by the conducting layer.

In an embodiment of the present disclosure, the conducting layer is formed on the array substrate, and the separator directly contacts with the conducting layer.

In an embodiment of the present disclosure, the conducting layer is formed on an outermost side of at least one thin film transistor channel of the array substrate.

In an embodiment of the present disclosure, a material of the conducting layer is a metal material or a conductive metal oxide material.

In an embodiment of the present disclosure, the material of the conducting layer is a transparent indium tin oxide material.

In an embodiment of the present disclosure, an end of the separator is opposite to at least one thin film transistor on the array substrate.

In an embodiment of the present disclosure, the separator is a pillar separator.

In an embodiment of the present disclosure, the separator is tapered in a direction extending towards the array substrate.

In an embodiment of the present disclosure, the separator is a main separator disposed on a blue pixel.

In an embodiment of the present disclosure, the separator comprises an alignment film.

In an embodiment of the present disclosure, a via hole is disposed on a surface of the array substrate facing the opposite substrate, the via hole extends to the gate electrode, and the conducting layer is connected to the gate electrode through the via hole.

In an embodiment of the present disclosure, a conductive medium is disposed in the via hole for electrically conducting the conducting layer and the gate electrode; or a portion of the conducting layer passes through the via hole to electrically connect to the gate electrode.

In an embodiment of the present disclosure, a conducting ring for eliminating static electricity is disposed on a periphery of the display panel, and the conducting ring is electrically connected with the gate electrode.

The present disclosure also provides a display device including a display panel and a driving circuit connected with the display panel, wherein, the display panel is the aforementioned display panel.

### BRIEF DESCRIPTION OF DRAWINGS

FIG. 1 is a schematic partial sectional view of a display panel according to an embodiment of the present disclosure in one direction.

FIG. 2 is a schematic partial sectional view of a display panel according to an embodiment of the present disclosure in another different direction.

### DETAILED DESCRIPTION

Currently, there is a phenomenon of poor blue spot in LCD panels. The inventors of the present application find that the cause for poor blue spot is as follows: because of external knocking and vibration and the like, the main separator (PS) (comprising polyimide (PI) alignment film) disposed on blue pixels rubs the thin film transistor (TFT) element to produce a charge accumulation, such that the TFT leakage current (Ioff) increases, and the pixel voltage cannot be maintained, resulting in poor blue spot.

In this regard, the present disclosure provides a display panel which can reduce the possibility of occurrence of the poor blue spot problem.

The embodiments of the present disclosure will be described in detail below. The examples of the embodiments are shown in the drawings, throughout which identical or similar reference numbers indicate identical or similar elements or elements having identical or similar functions. The embodiments described below with reference to the drawings are exemplary, and are intended to illustrate the present invention, but cannot be understood to limit the present invention.

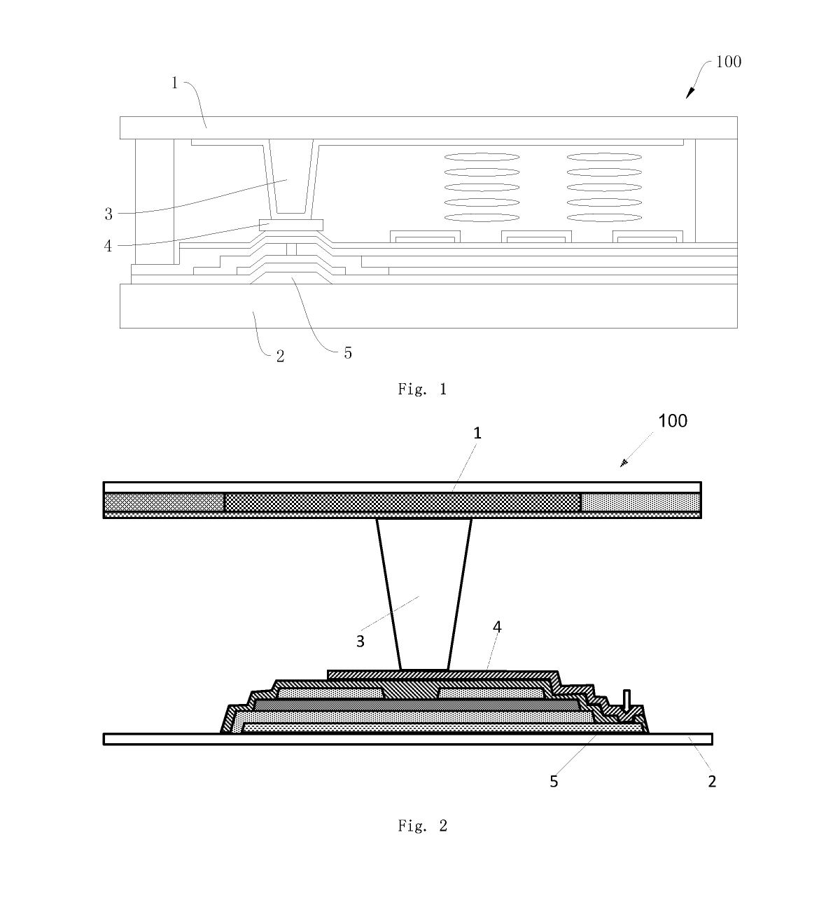

As shown in FIG. 1, a display panel 100 according to an embodiment of the present disclosure includes an opposite substrate 1, an array substrate 2 and a separator 3.

Specifically, the opposite substrate 1 and the array substrate 2 are substrates at least portions of which are separated from each other, and the opposite substrate 1 and the array substrate 2 are supported by the separator 3. In case that vibration, external knocking or the like occurs in the display panel 100, the separator 3 may rub an element (for example, thin film transistor) on the array substrate 2 to produce a charge accumulation. In the present disclosure, a conducting layer 4 is disposed between the separator 3 and the array substrate 2, and the conducting layer 4 is connected with a gate electrode 5 on the array substrate 2. When charges are produced due to the friction of the separator 3, the electrostatic charges can be conducted to the gate electrode 5 through the conducting layer 4, thereby avoiding the problem that electrostatic charges accumulate on the display screen to produce a poor spot.

In the display panel 100 according to the embodiment of the present disclosure, because the conducting layer 4 is provided and the conducting layer 4 is connected with the gate electrode 5 on the array substrate 2, the electrostatic charges caused by friction can be conveniently conducted out, thereby reducing or avoiding the problem of poor blue spot (or red spot or spot with another color).

For example, in the case that the separator 3 is supported on blue pixel, when the main PS (comprising PI) disposed on the blue pixel rubs the TFT element (due to the external knocking, vibration or the like) to produce a charge accumulation, the charges are conducted to the gate electrode 5 through the conducting layer 4 (for example, a metal layer). If the charge accumulation amount is small, the charges are gradually dissipated when they are transmitted on the gate electrode 5; and if the charge accumulation amount is large, the charges can be conducted out to Vcom through a static electricity conducting ring.

The conducting layer 4 functions to conduct electricity, e.g. to conduct charges to the gate electrode 5. The actual coverage area of the conducting layer 4 is not required to be strictly limited, as long as charges can be conducted to the gate electrode 5 through the conducting layer 4. That is, the conducting layer 4 may be configured to cover a portion of an end surface of the separator 3, and even may be not required to cover the end surface of the separator 3.

Preferably, as shown in FIG. 1, the conducting layer 4 separates the separator 3 and the array substrate 2, and a coverage area of the conducting layer 4 is larger than an end surface of the separator 3 facing the array substrate 2. In other words, a projection of the end surface of the separator 3 towards the conducting layer 4 is covered by the conducting layer 4, or the projection of the end surface of the separator 3 towards the conducting layer 4 falls on the conducting layer 4. That is, the conducting layer 4 separates the separator 3 and the array substrate 2. Even if a friction occurs, the friction only occurs between the separator 3 and the conducting layer 4. In this manner, even if there are charges, the conducting layer 4 can conduct the charges out rapidly, thereby avoiding a charge accumulation and in turn reducing the problem of the occurrence of color spot.

Further, the disposing position of the conducting layer 4 is not limited in the present disclosure. Because the conducting layer 4 is used for electric conduction, whether the conducting layer 4 is disposed on the separator 3, or the conducting layer 4 is disposed on the array substrate 2, the charge conduction will not be influenced. Preferably, the conducting layer 4 is formed on the array substrate 2. In this manner, the conducting layer 4 can be conveniently connected with the gate electrode 5 on the array substrate 2, and conduct the charges out rapidly. And it is relatively easier to form the conducting layer 4 on the array substrate 2. Further, for the reason that the display panel 100 may expand with heat and contract with cold and the like, if the conducting layer 4 is disposed on the separator 3, a problem of poor electric conduction between the conducting layer 4 and the gate electrode 5 may occur, which will also result in charge accumulation. Such problems can be solved by disposing the conducting layer 4 on the array substrate 2.

Further, the separator 3 is directly contacted with the conducting layer 4 to further improve the consumption efficiency of static electricity.

The conducting layer 4 may be made of an optical coating film. It is relatively easier to form the conducting layer 4 by optical film coating, and the adherence of the conducting layer 4 is stable, thereby avoiding the exfoliation of the conducting layer 4 and being convenient for the integral forming of the array substrate 2.

Of course, the conducting layer 4 may also be formed in other methods such as magnetron sputtering, physical vapor deposition, thin film etching technology and the like.

Further, for the convenience of conducting charges out by the conducting layer 4, the conducting layer 4 may be a metal layer, or a material of the conducting layer may be a metal material. Good conductivity of the metal layer allows rapid conduction of charges, such that charges can be conducted out rapidly when the system encounters vibration or the like.

For example, the conducting layer 4 may be a copper material layer, an aluminum material layer or the like.

The conducting layer 4 may also be a conductive metal oxide or the like, or the material of the conducting layer 4 may be a conductive metal oxide. For example, the conducting layer 4 is a transparent indium tin oxide (ITO) conducting layer. In other words, the material of the conducting layer 4 is a transparent indium tin oxide material. The transparent conducting layer 4 avoids influencing the display of the display panel 100, thereby improving the display effect of the display panel 100.

The separator 3 may be a pillar separator. As shown in FIG. 1, in an embodiment of the present disclosure, the size of an end of the separator 3 supporting the opposite substrate 1 is larger than the size of an end of the separator 3 supporting the array substrate 2. Preferably, the separator 3 is tapered in a direction extending towards the array substrate.

Preferably, as shown in FIG. 1, an end of the separator 3 is opposite to at least one thin film transistor on the array substrate 2. Likewise, the conducting layer 4 disposed between the separator 3 and the array substrate 2 can be conveniently connected with the gate electrode 5 of the thin film transistor, which simplifies the structure of the display panel 100 and is convenient for conducting charges to the gate electrode 5.

Further, the display panel 100 may be a thin film transistor display panel 100.

Preferably, as shown in FIG. 2, a via hole is disposed on a surface of the array substrate 2 facing the opposite substrate 1, the via hole extends to the gate electrode 5, and the conducting layer 4 is connected to the gate electrode 5 through the via hole. By disposing the via hole, the conducting layer 4 can be electrically conducted with the gate electrode 5 to thereby achieve the dissipation of electrostatic charges on the conducting layer 4 and the separator 3.

Here, FIG. 2 shows how the conducting layer is connected with the gate electrode through the via hole. Because the conducting layer passes through the via hole, the via hole cannot be designated, as can be easily understood by those skilled in the art.

Further, a conductive medium may be disposed in the via hole. The conducting layer is conducted with the gate electrode through the conductive medium, thereby achieving the electrical connection between the conducting layer and the gate electrode. Further, a portion of the conducting layer may pass through the via hole to directly connect with the gate electrode, thereby simplifying the process, reducing the cost, and lowering the process difficulty.

Further, a conducting ring may be disposed in the display panel for eliminating electrostatic electricity in the display panel. In general, the conducting ring is disposed on the periphery of the display panel. In the present disclosure, the electrostatic electricity on the conducting layer may be eliminated through the conducting ring. For example, the conducting layer is directly connected with the conducting ring, or the conducting layer is connected with the gate electrode and the gate electrode is connected with the conducting ring. Here, when the amount of the electrostatic charges on the conducting layer is small, the dissipation of the electrostatic charges can be achieved through the gate electrode. And when the amount of the electrostatic charges on the conducting layer is large, the electrostatic charges can be eliminated through the conducting ring.

The display panel 100 according to a particular embodiment of the present disclosure will be described below with reference to the drawings.

FIG. 1 and FIG. 2 are schematic partial sectional views of the display panel 100 according to a particular embodiment of the present disclosure in different directions. As in FIG. 1, the display panel 100 has a structure in which a metal layer (conducting layer 4) is added to the outermost side of the TFT contacted with the main PS, based on existing LCD display panel. The metal layer has good conductivity, and the metal layer is connected with a gate electrode 5 through a via hole (as shown in FIG. 2). Electrostatic electricity on the metal layer can be conducted out through the gate electrode 5 in a time-sharing driving manner, thereby reducing the occurrence of poor blue spot in the display panel 100 and improving the display effect.

The metal layer may be fabricated by a film-coating or etching process. As shown in FIG. 1, the metal layer is located at the outermost layer of the TFT channel corresponding to the main PS supporting position, and it is ensured that the contact area between the main PS and the metal layer satisfies the design requirement. The metal layer is connected and conducted with the gate electrode 5 through the via hole.

Further, the present disclosure also provides a display device including a display panel and a driving circuit connected with the display panel, wherein, the display panel is the aforementioned display panel 100. Because of the use of the display panel 100, the display device of the present disclosure can reduce the occurrence of the problem of color spot, thereby improving the display effect of the display device.

In the description of this specification, the description with reference to term “an embodiment”, “some embodiments”, “example”, “particular example”, “some examples”, or the like means that the particular feature, structure, material or characteristic described with reference to the embodiment or example is included in at least one embodiment or example of the present disclosure. In this specification, the exemplary expressions of the above terms are not required to refer to the same embodiment or example. And the particular feature, structure, material or characteristic described can be combined in a suitable manner in one or more embodiments or examples. Further, without contradicting with each other, different embodiments or examples as well as the features of different embodiments or examples described in this specification can be combined by those skilled in the art.

Although the embodiments of the present disclosure have been shown and described above, it should be understood that the above embodiments are exemplary, and should not be construed as limiting the present disclosure. A person of ordinary skills in the art can make change, modification, replacement and variation on the above embodiments within the scope of the present disclosure.

What is claimed is:

1. A display panel comprising:
an array substrate;
an opposite substrate; and
a separator positioned between the array substrate and the opposite substrate to support the array substrate and the opposite substrate;
wherein the display panel further includes a conducting layer disposed between the separator and the array substrate and electrically connected with a gate electrode on the array substrate.

2. The display panel according to claim 1, wherein, the conducting layer separates the separator and the array substrate, and a projection of an end surface of the separator facing the array substrate towards the conducting layer is covered by the conducting layer.

3. The display panel according to claim 1, wherein, the conducting layer is formed on the array substrate, and the separator directly contacts with the conducting layer.

4. The display panel according to claim 3, wherein, the conducting layer is formed on an outermost side of at least one thin film transistor channel of the array substrate.

5. The display panel according to claim 1, wherein, the conducting layer is made of a metal material or a conductive metal oxide material.

6. The display panel according to claim 5, wherein, the conducting layer is made of a transparent indium tin oxide material.

7. The display panel according to claim 1, wherein, an end of the separator is opposite to at least one thin film transistor on the array substrate.

8. The display panel according to claim 1, wherein, the separator is a pillar separator.

9. The display panel according to claim 8, wherein, the separator is tapered in a direction extending towards the array substrate.

10. The display panel according to claim 1, wherein, the separator is a main separator disposed on a blue pixel.

11. The display panel according to claim 10, wherein, the separator comprises an alignment film.

12. The display panel according to claim 1, wherein, a via hole is disposed on a surface of the array substrate facing the opposite substrate, the via hole extends to the gate electrode, and the conducting layer is connected to the gate electrode through the via hole.

13. The display panel according to claim 12, wherein:
a conductive medium is disposed in the via hole for electrically conducting the conducting layer and the gate electrode; or
a portion of the conducting layer passes through the via hole to electrically connect to the gate electrode.

14. The display panel according to claim 1, wherein, a conducting ring for eliminating static electricity is disposed on a periphery of the display panel, and the conducting ring is electrically connected with the gate electrode.

15. A display device including a display panel and a driving circuit connected with the display panel, wherein, the display panel is the display panel according to claim 1.

16. A display device including a display panel and a driving circuit connected with the display panel, wherein, the display panel is the display panel according to claim 2.

17. A display device including a display panel and a driving circuit connected with the display panel, wherein, the display panel is the display panel according to claim 3.

18. A display device including a display panel and a driving circuit connected with the display panel, wherein, the display panel is the display panel according to claim 4.

19. A display device including a display panel and a driving circuit connected with the display panel, wherein, the display panel is the display panel according to claim 12.

20. A display device including a display panel and a driving circuit connected with the display panel, wherein, the display panel is the display panel according to claim 14.
